(19) United States
(12) Patent Application Publication
(10) Pub. No.: US 2025/0343101 A1
(43) Pub. Date: Nov. 6, 2025

(54) POWER MODULE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Yuichi SAWAHARA, Sagamihara Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/189,392

(22) Filed: Apr. 25, 2025

(30) Foreign Application Priority Data
May 1, 2024 (JP) 2024-074389

(51) Int. Cl. H01L 23/373; H01L 23/367; H01L 23/538; H01L 25/18; H10D 1/68

(52) U.S. Cl. CPC H01L 23/3735; H01L 23/3672; H01L 23/5383; H01L 23/5386; H01L 25/18; H10D 1/68

(57) ABSTRACT

According to one embodiment, a power module including a first conductive pattern, a second conductive pattern, a first power device, a third conductive pattern, a first capacitive element, a fourth conductive pattern, a second capacitive element, a first conductive plug, a fifth conductive pattern, a second conductive plug, and a second power device is provided. In the power module, a first power loop and a second power loop are formed. The first power loop includes the first conductive pattern, the first power device, the second conductive pattern, the first capacitive element, the third conductive pattern, and the second power device. The second power loop includes the first conductive pattern, the first power device, the first conductive plug, the fifth conductive pattern, the second conductive plug, the fourth conductive pattern, the second capacitive element, the third conductive pattern, and the second power device.

### CROSS-REFERENCE TO RELATED APPLICATIONS

This application is based upon and claims the benefit of priority from Japanese Patent Application No. 2024-074389, filed on May 1, 2024; the entire contents of which are incorporated herein by reference.

### FIELD

Embodiments described herein relate generally to a power module.

### BACKGROUND

In a power module on which a power device is mounted, a power loop including the power device may be formed. In the power module, it is desired that the power loop is appropriately formed.

### BRIEF DESCRIPTION OF THE DRAWINGS

FIG. 1 is a perspective view illustrating a configuration of a power module according to a first embodiment;

FIG. 2 is a plan view illustrating the configuration of the power module according to the first embodiment;

FIG. 3 is a cross-sectional view illustrating the configuration of the power module in the first embodiment;

FIG. 4 is a cross-sectional view illustrating the configuration of the power module in the first embodiment;

FIG. 5 is a view illustrating a power loop in the first embodiment;

FIG. 6 is a circuit diagram illustrating a configuration of the power module according to the first embodiment;

FIG. 7 is a diagram illustrating a ratio of frequency components for each power loop in the first embodiment;

FIG. 8 is a perspective view illustrating a configuration of a power module according to a second embodiment;

FIG. 9 is a plan view illustrating the configuration of the power module according to the second embodiment;

FIG. 10 is a view illustrating a power loop in the second embodiment;

FIG. 11 is a plan view illustrating a configuration of a power module according to a third embodiment;

FIG. 12 is a view illustrating a power loop in the third embodiment;

FIG. 13 is a plan view illustrating a configuration of a power module according to a fourth embodiment;

FIG. 14 is a view illustrating a power loop in the fourth embodiment;

FIG. 15 is a plan view illustrating a configuration of a power module according to a fifth embodiment; and

FIG. 16 is a view illustrating a power loop in the fifth embodiment.

### DETAILED DESCRIPTION

In general, according to one embodiment, there is provided a power module including a first conductive pattern, a second conductive pattern, a first power device, a third conductive pattern, a first capacitive element, a fourth conductive pattern, a second capacitive element, a first conductive plug, a fifth conductive pattern, a second conductive plug, and a second power device. The first conductive pattern is included in the first layer. The second conductive pattern is disposed on the first layer. The first power device is disposed between the first conductive pattern and the second conductive pattern in the first layer. The third conductive pattern is disposed on the first layer. The first capacitive element is disposed between the second conductive pattern and the third conductive pattern in the first layer. The fourth conductive pattern is disposed on the first layer. The second capacitive element is disposed between the third conductive pattern and the fourth conductive pattern in the first layer. The first conductive plug extends from the first layer to the second layer, and has one end electrically connected to one end of the second conductive pattern. The fifth conductive pattern is included in the second layer, and has one end electrically connected to another end of the first conductive plug. The second conductive plug extends from the second layer to the first layer, and has one end electrically connected to another end of the fifth conductive pattern and another end electrically connected to the fourth conductive pattern. The second power device is disposed between the first conductive pattern and the third conductive pattern in the first layer. A first power loop including the first conductive pattern, the first power device, the second conductive pattern, the first capacitive element, the third conductive pattern, and the second power device, and a second power loop including the first conductive pattern, the first power device, the first conductive plug, the fifth conductive pattern, the second conductive plug, the fourth conductive pattern, the second capacitive element, the third conductive pattern, and the second power device are formed.

Exemplary embodiments of a power module will be explained below in detail with reference to the accompanying drawings. The present invention is not limited to the following embodiments.

### First Embodiment

In the power module according to the first embodiment, a power device is mounted and a power loop including the power device is formed, but a device for appropriately forming the power loop including the power device is provided.

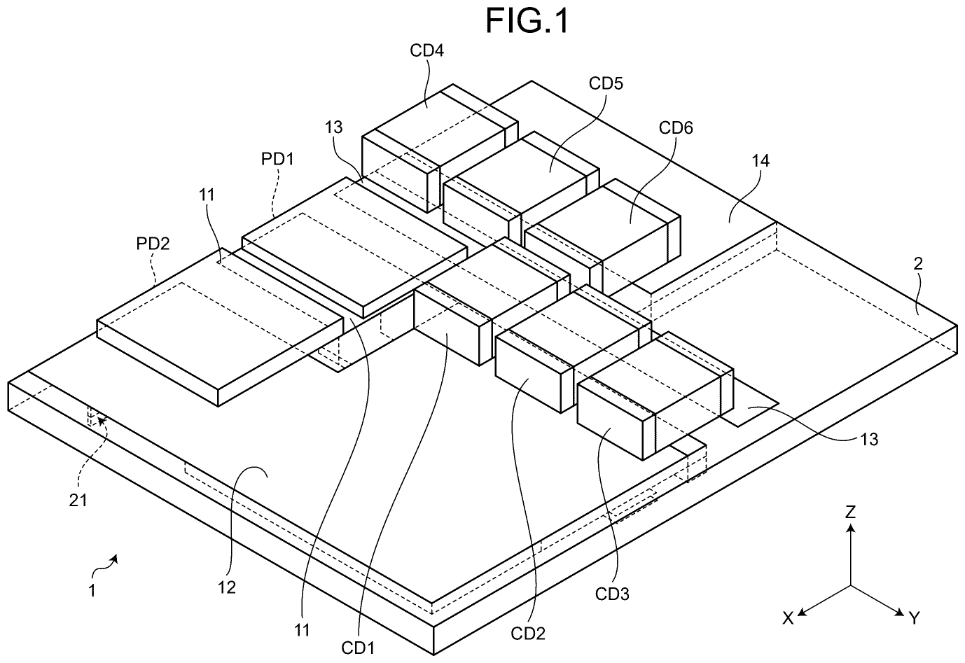

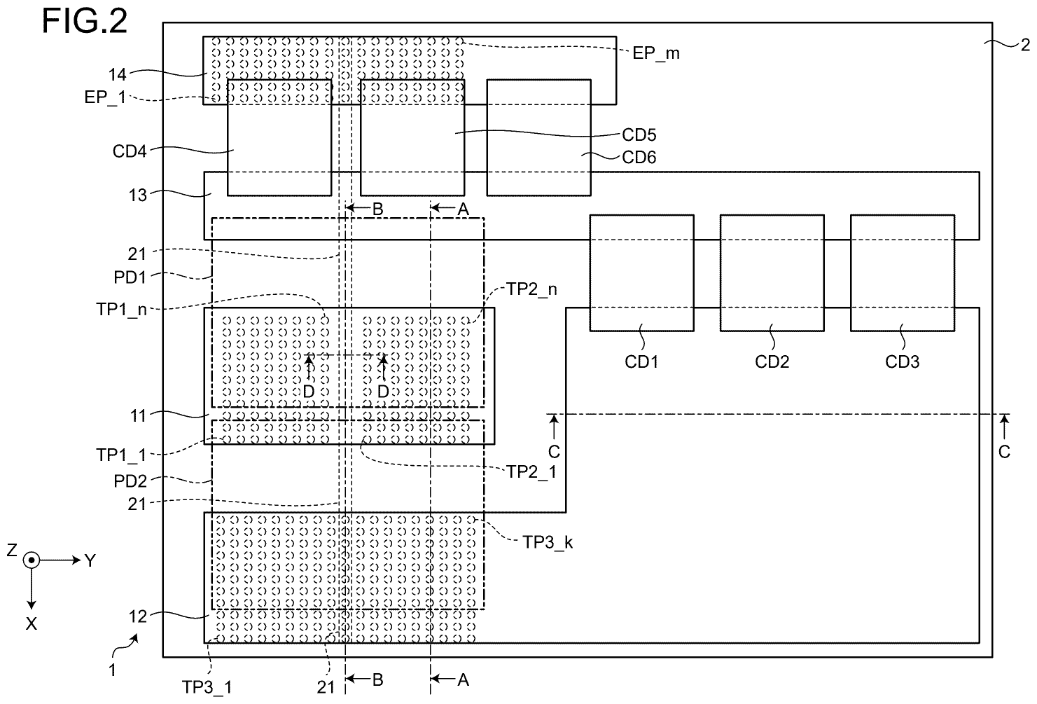

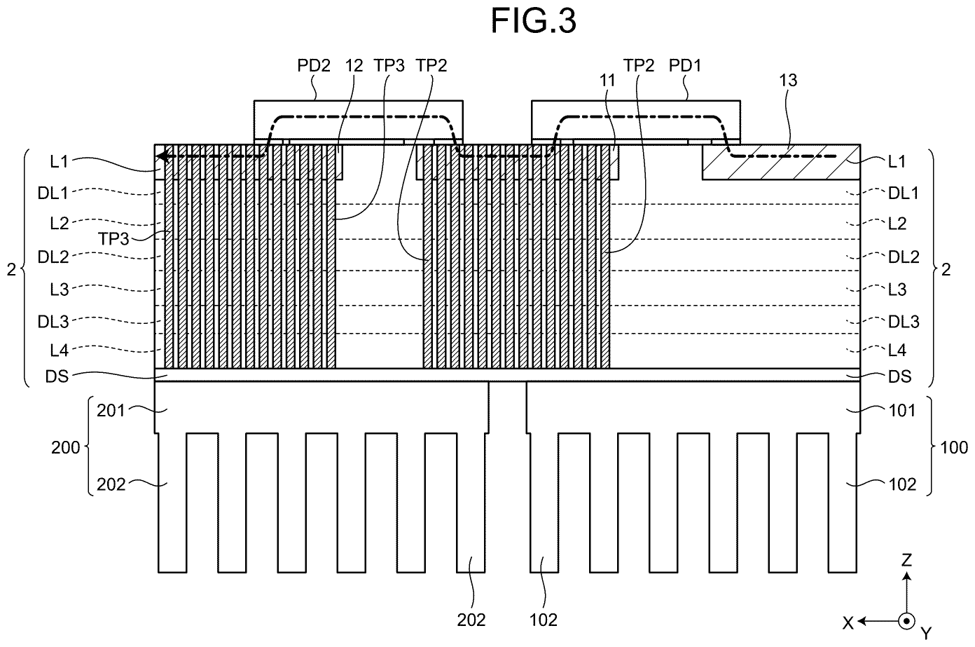

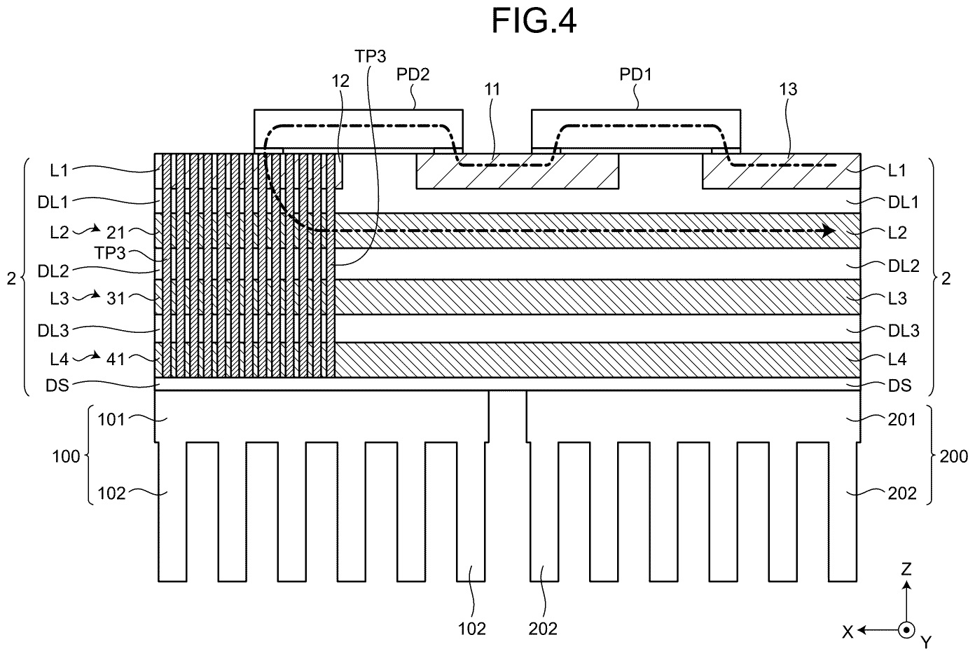

The power module 1 can be configured as illustrated in FIGS. 1 to 4. FIG. 1 is a perspective view illustrating a configuration of a power module 1. FIG. 2 is a plan view illustrating the configuration of the power module 1. In FIG. 2, a planar configuration in which power devices PD1 and PD2 are removed is illustrated, and arrangement regions of the power devices PD1 and PD2 are indicated by two-dot chain lines. FIG. 3 is a cross-sectional view illustrating the configuration of the power module 1, and illustrates a cross section taken along line A-A in FIG. 2 as viewed in the direction of an arrow. FIG. 4 is a cross-sectional view illustrating the configuration of the power module 1, and illustrates a cross section taken along line B-B in FIG. 2 as viewed in the direction of an arrow.

The power module 1 includes a multilayer substrate 2, power devices PD1 and PD2, capacitive devices CD1 to CD6, multiple heat conductive plugs TP1_1 to TP1_n, TP2_1 to TP2_n, TP3_1 to TP3_k, and heat dissipation members 100 and 200. n is any integer equal to or more than 2. k is any integer equal to or more than 2.

In the multilayer substrate 2, as illustrated in FIGS. 3 and 4, an insulating sheet DS, a wiring layer L4, an insulating layer DL3, a wiring layer L3, an insulating layer DL2, a wiring layer L2, an insulating layer DL1, and a wiring layer L1 are sequentially stacked in a Z direction. In the multilayer substrate 2, a conductive plug EP may be further arranged between the wiring layer L1 and the wiring layer L2 in the Z direction. The insulating sheet DS entirely covers at least a surface where the wiring layer L4 and the heat dissipation members 100 and 200 can be in contact with each other.

The heat conductive plugs TP1_1 to TP1_n and TP2_1 to TP2_n are arranged between the power devices PD1 and PD2 and the heat dissipation members 100 and 200 in the Z direction. An end on a +Z side of each of the heat conductive plugs TP1 and TP2 is electrically connected to the wiring layer L1 and is in thermal contact with packages of the power devices PD1 and PD2. An end on a −Z side of each of the heat conductive plugs TP1 and TP2 is electrically insulated from the heat dissipation member 100 with the insulating sheet DS interposed therebetween and is in thermal contact with the heat dissipation member 100.

The heat conductive plugs TP1_1 to TP1_n are arranged corresponding to the −Y side in the arrangement region of the power device PD1. The heat conductive plugs TP2_1 to TP2_n are arranged corresponding to the +Y side in the arrangement region of the power device PD1.

The heat dissipation member 100 includes a flat plate portion 101 and multiple fin portions 102. The flat plate portion 101 is in thermal contact with each of the heat conductive plugs TP1 and TP2 with the insulating sheet DS interposed therebetween. Each fin portion 102 protrudes in a fin shape on the opposite side (−Z side) of the multilayer substrate 2.

The heat conductive plugs TP3_1 to TP3_k are arranged between the power device PD2 and the heat dissipation member 200 in the Z direction. An end on a +Z side of each of the heat conductive plugs TP3 is electrically connected to the wiring layer L1 and is in thermal contact with the package of the power device PD2. An end on a −Z side of each of the heat conductive plugs TP3 on the −Z side is electrically insulated from the heat dissipation member 200 with the insulating sheet DS interposed therebetween and is in thermal contact with the heat dissipation member 200.

The heat dissipation member 200 includes a flat plate portion 201 and multiple fin portions 202. The flat plate portion 201 is in thermal contact with each heat conductive plug TP3 with the insulating sheet DS interposed therebetween. Each fin portion 202 protrudes in a fin shape on the opposite side (−Z side) of the multilayer substrate 2.

The wiring layer L1 extends in X and Y directions. The wiring layer L1 is a wiring layer on the most +Z side in the multilayer substrate 2. As illustrated in FIGS. 1 and 2, the wiring layer L1 includes a conductive pattern 11, a conductive pattern 12, a conductive pattern 13, and a conductive pattern 14. The power devices PD1 and PD2 are disposed in the wiring layer L1. The capacitive devices CD1 to CD6 are disposed in the wiring layer L1.

The power device PD1 is electrically connected between the conductive pattern 11 and the conductive pattern 13. The power device PD1 may have a substantially rectangular shape in XY plan view. The power device PD1 has a main surface perpendicular to the Z direction. The power device PD1 may have the Y direction as a longitudinal direction and the X direction as a shorter direction. The power device PD1 has one end connected to the conductive pattern 13 and the other end connected to the conductive pattern 11 in the X direction. The power device PD1 includes a switching element and is controlled to perform a switching operation.

The conductive pattern 11 is electrically connected between the power device PD1 and the power device PD2. The conductive pattern 11 extends at least in the X direction. The conductive pattern 11 may further extend in the Y direction. The conductive pattern 11 may have a substantially rectangular shape in XY plan view. One end of the conductive pattern 11 on the +X side is electrically connected to the conductive pattern 13 via the power device PD2, and the other end on the −X side is electrically connected to the conductive pattern 12 via the power device PD1.

The power device PD2 is electrically connected between the conductive pattern 11 and the conductive pattern 12. The power device PD2 may have a substantially rectangular shape in XY plan view. The power device PD1 has a main surface perpendicular to the Z direction. The power device PD2 may have the Y direction as a longitudinal direction and the X direction as a shorter direction. The power device PD2 has one end connected to the conductive pattern 11 and the other end connected to the conductive pattern 12 in the X direction. The power device PD2 includes a switching element and is controlled to perform a switching operation.

The heat conductive plugs TP1_1 to TP1_n are arranged corresponding to the −Y side in the arrangement region of the conductive pattern 11. The heat conductive plugs TP1_1 to TP1_n penetrate the conductive pattern 11 and are in contact with −Z side surfaces of the packages of the power devices PD1 and PD2. The heat conductive plugs TP1_1 to TP1_n may penetrate all the wiring layers L1 to L4 between the power devices PD1 and PD2 and the heat dissipation members 100 and 200, or may penetrate some of the wiring layers L2 to L4. In the case of penetrating some of the wiring layers L2 to L4, the heat conductive plugs TP1_1 to TP1_n may be electrically insulated from the conductive pattern 11 with the insulating layer DL1 interposed therebetween.

The heat conductive plugs TP2_1 to TP2_n are arranged corresponding to the +Y side in the arrangement region of the conductive pattern 11. The heat conductive plugs TP2_1 to TP2_n penetrate the conductive pattern 11 and are in contact with the −Z side surfaces of the packages of the power devices PD1 and PD2. The heat conductive plugs TP2_1 to TP2_n may penetrate all the wiring layers L1 to L4 between the power devices PD1 and PD2 and the heat dissipation members 100 and 200, or may penetrate some of the wiring layers L2 to L4. In the case of penetrating some of the wiring layers L2 to L4, the heat conductive plugs TP2_1 to TP2_n may be electrically insulated from the conductive pattern 11 with the insulating layer DL1 interposed therebetween.

The conductive pattern 12 is electrically connected between the power device PD2 and the capacitive devices CD1 to CD3. One end of the conductive pattern 12 is electrically connected to the power device PD2. The conductive pattern 12 extends from the position to a position separated to the +Y side with respect to the power device PD2, is bent to the −X side from the separated position, and extends in the X direction. The conductive pattern 12 may have a substantially L shape in XY plan view. The conductive pattern 12 has one end disposed on the +X side and the −Y side and the other end disposed on the −X side.

The heat conductive plugs TP3_1 to TP3_k are arranged corresponding to the +X side and the −Y side in the arrangement region of the conductive pattern 12. The heat conductive plugs TP3_1 to TP3_k penetrate the conductive pattern 12 and are in contact with the −Z side surface of the package of the power device PD2. The heat conductive plugs TP3_1 to TP3_k may be made of a material having thermal conductivity and electrical conductivity. The heat conductive plugs TP3_1 to TP3_k can also function as conductive plugs. The heat conductive plugs TP3_1 to TP3_k may be electrically connected to the conductive pattern 12. Some of the heat conductive plugs TP3 in the heat conductive plugs TP3_1 to TP3_k may be electrically connected to a conductive pattern 21.

The capacitive devices CD1 to CD3 are

electrically connected between the conductive pattern 12 and the conductive pattern 13. Each of the capacitive devices CD1 to CD3 may have a substantially rectangular shape in XY plan view. Each of the capacitive devices CD1 to CD3 may have the X direction as a longitudinal direction and the Y direction as a shorter direction. One end of each of the capacitive devices CD1 to CD3 is connected to the conductive pattern 12, and the other end is connected to the conductive pattern 13 in the X direction.

The conductive pattern 13 is electrically connected among the power device PD1, the capacitive devices CD1 to CD3, and the capacitive devices CD4 to CD6. The conductive pattern 13 mainly extends in the Y direction. The conductive pattern 13 may have a substantially lateral I-shape in XY plan view. In the conductive pattern 13, a portion on the +X side and the +Y side is connected to the conductive pattern 12 via the capacitive devices CD1 to CD3, a portion on the −X side is connected to the conductive pattern 14 via the capacitive devices CD4 to CD6, and a portion on the +X side and the −Y side is connected to the conductive pattern 11 via the power device PD1.

The capacitive devices CD4 to CD6 are electrically connected between the conductive pattern 13 and the conductive pattern 14. Each of the capacitive devices CD4 to CD6 may have a substantially rectangular shape in XY plan view. Each of the capacitive devices CD4 to CD6 may have the X direction as a longitudinal direction and the Y direction as a shorter direction. One end of each of the capacitive devices CD4 to CD6 is connected to the conductive pattern 13, and the other end is connected to the conductive pattern 14 in the X direction.

The conductive pattern 14 is electrically connected to the capacitive devices CD4 to CD6. The conductive pattern 14 mainly extends in the Y direction. The conductive pattern 14 may have a substantially rectangular shape in XY plan view. A portion of the conductive pattern 14 on the +X side is connected to the conductive pattern 13 via the capacitive devices CD4 to CD6.

Conductive plugs EP_1 to EP_m are arranged corresponding to the −Y side in the arrangement region of the conductive pattern 14. Some of the conductive plugs EP in the conductive plugs EP_1 to EP_m may extend in the Z direction from the −Z side surface of the conductive pattern 14 to penetrate the wiring layers L1 to L4, or may extend to the conductive pattern of the wiring layer L2. The conductive plug EP can electrically connect the conductive pattern 14 and the conductive pattern of the wiring layer L2.

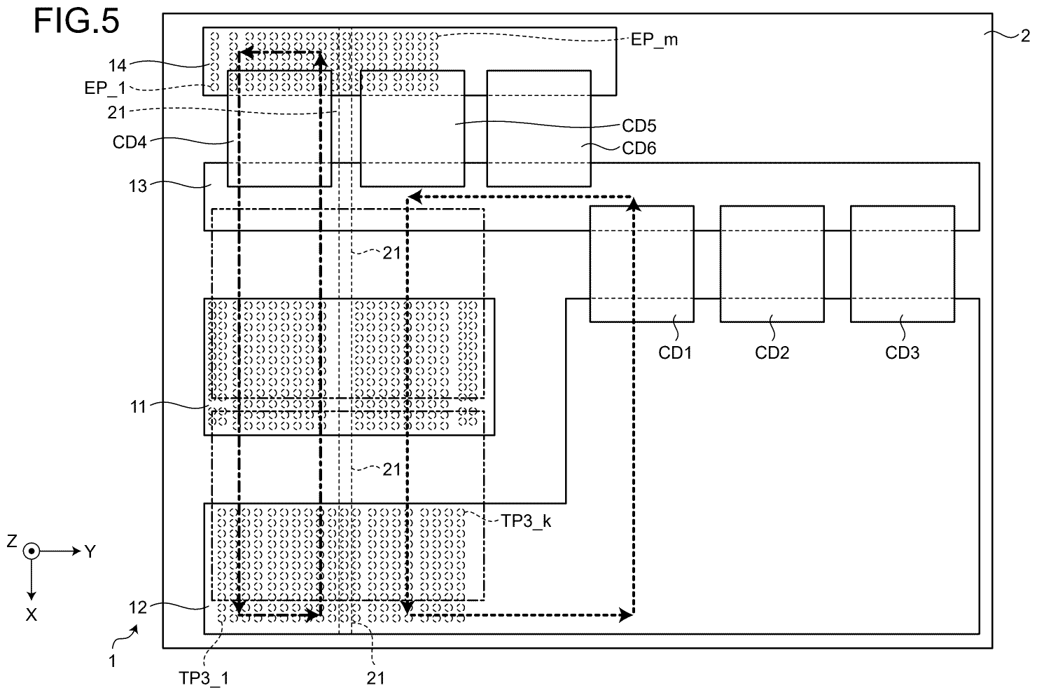

In the power module 1, as indicated by a dotted arrow in FIG. 5, a loop of the conductive pattern 13→the power device PD1→the conductive pattern 11→the power device PD2→the conductive pattern 12→the capacitive devices CD1 to CD3→the conductive pattern 13 forms a power loop in a shorter direction (X and Y directions). The power loop in the shorter direction will be referred to as a lateral loop.

The wiring layer L2 extends in the X and Y directions. The wiring layer L2 is the second wiring layer from the +Z side in the multilayer substrate 2. As illustrated in FIGS. 1, 2, and 4, the wiring layer L2 includes a conductive pattern 21.

The conductive pattern 21 is disposed on the-Z side of the conductive pattern 12 and the conductive pattern 14. The conductive pattern 21 may have a linear shape in XY plan view. The conductive pattern 21 extends in the X direction. The conductive pattern 21 may extend linearly in the X direction. The conductive pattern 21 extends in the X direction from the XY position of one end of the conductive pattern 12 to reach the XY position of the conductive pattern 14. One end of the conductive pattern 21 is connected to the conductive pattern 12 via the heat conductive plugs TP3_1 to TP3_k, and the other end is connected to the conductive pattern 14 via the conductive plugs EP_1 to EP_m. m is an integer of 2 or more.

The conductive plug EP may extend from the wiring layer L1 to the wiring layer L2 in the Z direction or may extend to the wiring layer L4. The conductive plug EP is disposed in a region including the XY position of the other end (−X side end) of the conductive pattern 21. Multiple the conductive plugs EP may be provided. FIG. 2 illustrates a configuration in which m conductive plugs EP_1 to EP_m are provided.

In the power module 1, as indicated by one-dot chain line arrows in FIG. 5, a loop of the conductive pattern 13→the power device PD1→the conductive pattern 11→the power device PD2→the conductive pattern 12→the heat conductive plugs TP3_1 to TP3_k-the conductive pattern 21→the conductive plugs EP_1 to EP_m→the conductive pattern 14→the capacitive devices CD4 to CD6→the conductive pattern 13 forms a power loop in a vertical direction (XZ direction). The power loop in the vertical direction is referred to as a vertical loop.

That is, in the power module 1, a hybrid structure of a lateral loop indicated by a dotted line in FIG. 5 and a vertical loop indicated by a one-dot chain line is configured. Thus, the power module 1 can suppress parasitic inductance of the power loop and improve high-frequency characteristics as compared with a case where the power loop is configured by a lateral loop and does not include a vertical loop. As compared with a case where the power loop is configured by a vertical loop and does not include a lateral loop, the power module 1 can suppress parasitic inductance of the power loop and can improve high-frequency characteristics.

For example, in the power module 1, the conductive pattern 21 of the wiring layer L2 can be miniaturized while improving the high-frequency characteristics. A width in the Y direction of the conductive pattern 21 is narrower than a width in the Y direction of the power device PD1. The width in the Y direction of the conductive pattern 21 is narrower than a width in the Y direction of the power device PD2. Thus, parasitic capacitance affecting output capacitance of the power devices PD1 and PD2 can be suppressed, and switching loss of the power devices PD1 and PD2 can be suppressed.

As the conductive pattern 21 can be miniaturized, as illustrated in FIGS. 2 and 3, a wide XY region where the conductive patterns of the wiring layers L2, L3, and L4 do not generally exist can be ensured between the power devices PD1 and PD2 and the heat dissipation members 100 and 200 in the Z direction.

For example, when viewed transparently from the Z direction, the conductive pattern 21 overlaps a part of the arrangement region of the conductive pattern 11 overlapping the power devices PD1 and PD2. In the arrangement region of the conductive pattern 11 overlapping the power devices PD1 and PD2, the heat conductive plugs TP1_1 to TP1_n and TP2_1 to TP2_n can be arranged in a region excluding the linear conductive pattern 21.

When viewed transparently from the Z direction, the conductive pattern 21 overlaps a part of the arrangement region of the conductive pattern 12 overlapping the power device PD2. The heat conductive plugs TP3_1 to TP3_k can be arranged in an arrangement region of the conductive pattern 12 overlapping the power device PD2.

Thus, the number n of the heat conductive plugs TP1 and TP2 and the number k of the heat conductive plugs TP3 between the power devices PD1 and PD2 and the heat dissipation members 100 and 200 can be increased, the heat of the power devices PD1 and PD2 can be efficiently transmitted to the heat dissipation members 100 and 200, and the heat can be efficiently dissipated from the heat dissipation members 100 and 200.

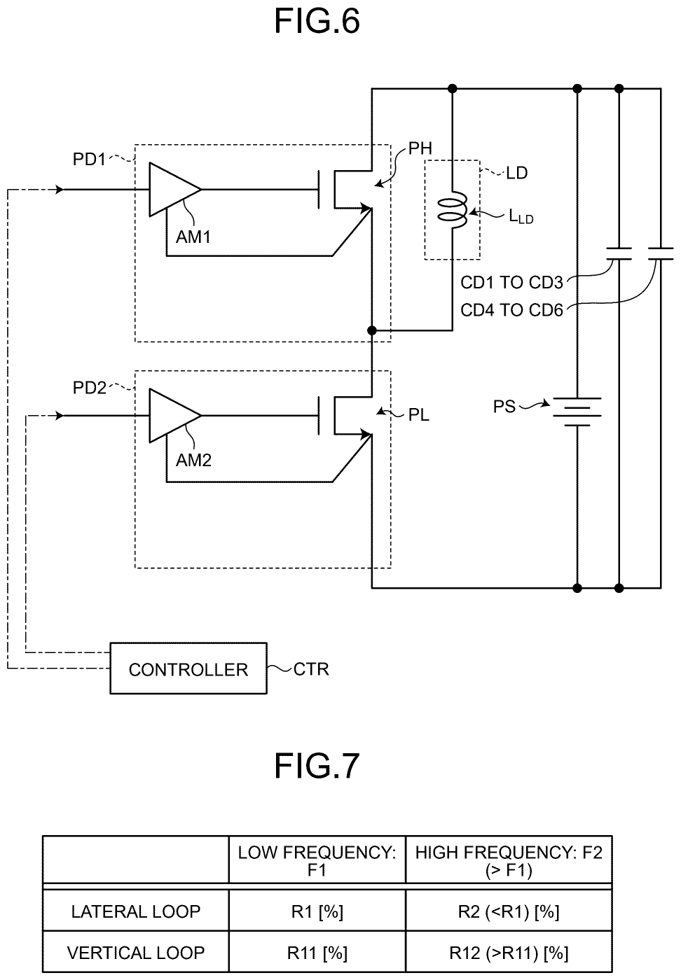

For example, an equivalent circuit of the power module 1 is as illustrated in FIG. 6. FIG. 6 is a circuit diagram illustrating a configuration of the power module 1.

The power module 1 includes power devices PD1 and PD2, a power supply PS, and a controller CTR. In the power module 1, a power loop of the power supply PS→the power device PD1→the power device PD2→the power supply PS is formed.

The power supply PS is a DC power supply and generates DC power. The power supply PS outputs a DC voltage with the other end as a reference from one end. One end of the power supply PS is referred to as a high voltage side, and the other end is referred to as a low voltage side. The power supply PS has a high-voltage side connected to the power device PD1 and a low-voltage side connected to the power device PD2.

The power device PD1 is connected in series between the power supply PS and the power device PD2. The power device PD1 includes an amplifier AM1 and a transistor PH. The transistor PH is an N-type transistor and may be an NMOSFET.

A load LD is connected in parallel to the power device PD1. The load LD may include at least one of a resistance component, a capacitance component, or an inductive component. In FIG. 6, the load LD including an inductive component L_{LD} is illustrated.

The power device PD2 is connected in series between the power device PD1 and the power supply PS. The power device PD2 includes an amplifier AM2 and a transistor PL. The transistor PL is an N-type transistor and may be an NMOSFET.

The controller CTR performs switching control of the power devices PD1 and PD2 according to a current flowing through the power loop. The controller CTR may perform switching control of the power devices PD1 and PD2 so that the current flowing through the power loop approaches the target value. Thus, DC power from the power supply PS can be converted into AC power by the power devices PD1 and PD2 and supplied to the load LD.

At this time, although the power devices PD1 and PD2 can generate heat, the heat of the power devices PD1 and PD2 can be efficiently dissipated from the heat dissipation members 100 and 200 by being efficiently transmitted to the heat dissipation members 100 and 200 by the heat conductive plugs TP1, TP2, and TP3.

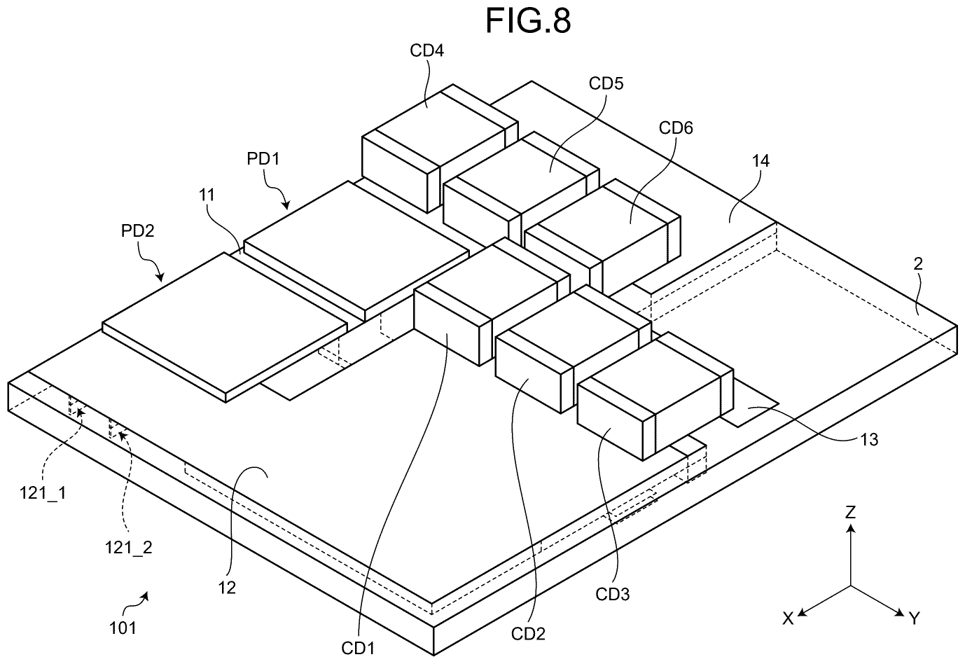

Next, frequency characteristics of each power loop in the hybrid structure will be described with reference to FIG. 7. FIG. 7 is a diagram illustrating a ratio of frequency components for each power loop.

For example, the magnitude of current i passing through a certain cross section is given by the following Formula 1.

$$i = {\int }_{s} Jds = {\int }_{l} Hdl \qquad Formula 1$$

The first and second terms of Formula 1 indicate that, when the area S of a certain cross section and current density J are known, the magnitude of the current i is obtained by performing surface integration of the current density J with the area S. The first and third terms of Formula 1 indicate that, when an outer peripheral length l of a certain cross section and a magnetic field H of a minute portion of the outer periphery are known, the magnitude of the current i is obtained by integrating the magnetic field H with the outer peripheral length l.

In FIG. 7, the ratio of a frequency component obtained using Formula 1 for a cross section of the conductive pattern 12 illustrated in FIG. 2 taken along line C-C is illustrated as the frequency characteristic of the lateral loop. A component of the frequency F1 is extracted as a low-frequency component L_{F1} and a component of the frequency F2 (>F1) is extracted as a high-frequency component L_{F2} from a spectrum obtained by Fourier-transforming the current i integrated with a cross section taken along line C-C. A ratio R1 of the low-frequency component L_{F1} is obtained by the following Formula 2.

$$R 1 = \{ {L}_{F 1} / ( {L}_{F 1} + {L}_{F 2} ) \} \times 100 \qquad Formula 2$$

A ratio R2 of the high-frequency component L_{F2} is obtained by the following Formula 3.

$$R 2 = \{ {L}_{F 2} / ( {L}_{F 1} + {L}_{F 2} ) \} \times 100 \qquad Formula 3$$

As a result of simulation on the frequency characteristics, it has been found that the ratio R1 of the low-frequency component L_{F1} tends to be larger than the ratio R2 of the high-frequency component L_{F2} in the lateral loop. For example, when F1=10 kHz and F2=500 MHZ, R1=about 75% and R2=about 35%.

In FIG. 7, the ratio of the frequency component obtained using Formula 1 for the cross section of the conductive pattern 21 illustrated in FIG. 2 taken along line D-D is illustrated as the frequency characteristic of the vertical loop. A component of the frequency F1 is extracted as a low-frequency component V_{F1} and a component of the frequency F2 (>F1) is extracted as a high-frequency component V_{F2} from a spectrum obtained by Fourier transforming the current i integrated with respect to the cross section cut by D-D line. A ratio R11 of the low-frequency component V_{F1} is obtained by the following Formula 4.

$$R 11 = \{ {V}_{F 1} / ( {V}_{F 1} + {V}_{F 2} ) \} \times 100 \qquad Formula 4$$

A ratio R12 of the high-frequency component L_{F2} is obtained by the following Formula 5.

$$R 12 = \{ {V}_{F 2} / ( {V}_{F 1} + {V}_{F 2} ) \} \times 100 \qquad Formula 5$$

When the frequency characteristics are simulated, it is found that the ratio R12 of the high-frequency component V_{F2} tends to be larger than the ratio R11 of the low-frequency component V_{F1} in the vertical loop. For example, when F1=10 kHz and F2=500 MHZ, R11=about 25% and R12=about 65%.

Thus, since the low-frequency characteristics can be ensured in the lateral loop and the high-frequency characteristics can be ensured in the vertical loop, it is confirmed that the frequency characteristics of the power module 1 can be ensured in a wide frequency band even if the conductive pattern 21 on the lower side (−Z side) in the vertical loop is miniaturized.

As described above, in the first embodiment, a hybrid structure of a lateral loop and a vertical loop is configured in the power module 1. Thus, the power module 1 can suppress parasitic inductance of the power loop and improve high-frequency characteristics as compared with a case where the power loop is configured by a lateral loop and does not include a vertical loop. As compared with a case where the power loop is configured by a vertical loop and does not include a lateral loop, the power module 1 can suppress parasitic inductance of the power loop and can improve high-frequency characteristics. That is, the frequency characteristics of the power module 1 can be ensured in a wide frequency band by the hybrid structure of the lateral loop and the vertical loop. Therefore, from this viewpoint, the power loop can be appropriately formed in the power module 1.

Further, in the first embodiment, in the power module 1, the conductive pattern 21 of the wiring layer L2 can be miniaturized while improving the high-frequency characteristics. Thus, the parasitic capacitance affecting the output capacitance of the power devices PD1 and PD2 can be suppressed, and the switching loss of the power devices PD1 and PD2 can be suppressed. Therefore, also from this viewpoint, the power loop can be appropriately formed in the power module 1.

Further, in the first embodiment, since the conductive pattern 21 of the wiring layer L2 can be miniaturized, a wide XY region where the conductive patterns of the wiring layers L2, L3, and L4 do not generally exist can be ensured between the power devices PD1 and PD2 and the heat dissipation members 100 and 200 in the Z direction. Thus, the number of heat conductive plugs TP between the power devices PD1 and PD2 and the heat dissipation members 100 and 200 can be increased, the heat of the power devices PD1 and PD2 can be efficiently transmitted to the heat dissipation members 100 and 200, and the heat can be efficiently dissipated from the heat dissipation members 100 and 200. Therefore, also from this viewpoint, the power loop can be appropriately formed in the power module 1.

### Second Embodiment

Next, a power module according to a second embodiment will be described. Hereinafter, portions different from those of the first embodiment will be mainly described.

In the first embodiment, a hybrid structure of one lateral loop and one vertical loop is illustrated, but in the second embodiment, a hybrid structure of one lateral loop and multiple vertical loops is illustrated.

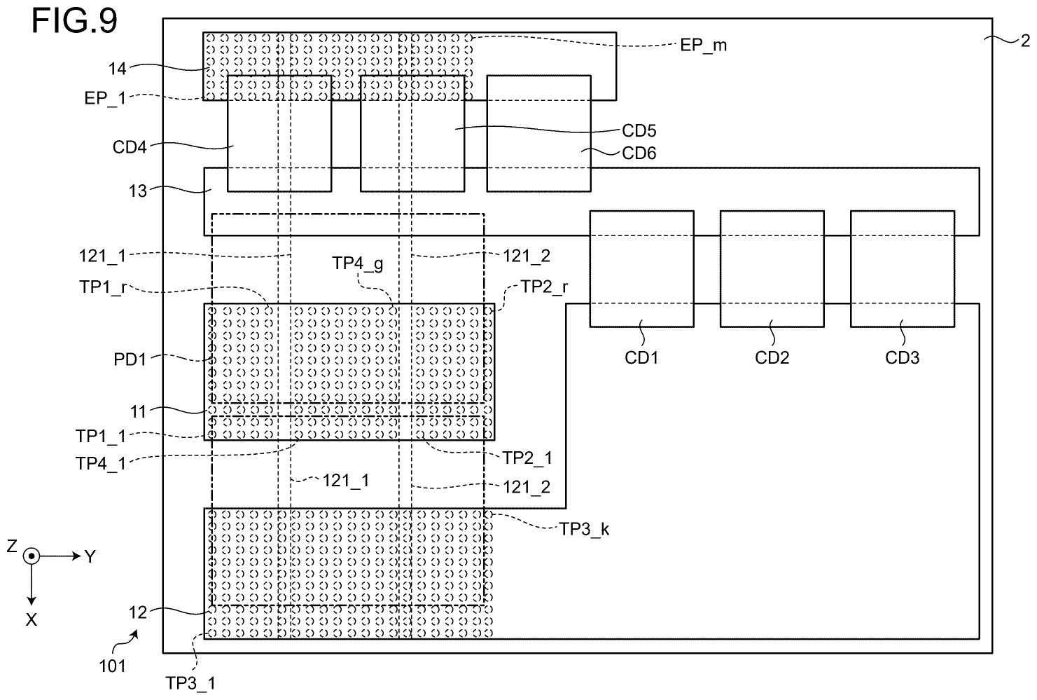

A power module 101 can be configured as illustrated in FIGS. 8 and 9. FIG. 8 is a perspective view illustrating a configuration of the power module 101. FIG. 9 is a plan view illustrating a configuration of the power module 101.

As illustrated in FIGS. 8 and 9, the wiring layer L2 includes multiple conductive patterns 121_1 and 121_2. In the wiring layer L2, the multiple conductive patterns 121_1 and 121_2 is disposed apart from each other in the X and Y directions.

The conductive pattern 121_1 is disposed on the −Z side of the conductive pattern 12 and the conductive pattern 14. The conductive pattern 121_1 is electrically connected between the conductive pattern 12 and the conductive pattern 14. The conductive pattern 121_1 may have a linear shape in XY plan view. The conductive pattern 121_1 extends in the X direction. The conductive pattern 121_1 extends in the X direction from the XY position of the conductive pattern 12 and reaches the XY position of the conductive pattern 14. The conductive pattern 121_1 has one end connected to the conductive pattern 12 via the heat conductive plugs TP3_1 to TP3_k and the other end connected to the conductive pattern 14 via the conductive plugs EP_1 to EP_m.

Some of the heat conductive plugs TP3 in the heat conductive plugs TP3_1 to TP3_k are arranged in the vicinity of the XY position of one end (+X side end) of the conductive pattern 121_1. One end (+Z side end) of the heat conductive plug TP3 is connected to the conductive pattern 12, and the other end (−Z side end) is connected to the conductive pattern 121_1.

Some of the conductive plugs EP in the conductive plugs EP_1 to EP_m are arranged in the vicinity of the XY position of the other end (−X side end) of the conductive pattern 121_1. One end (+Z side end) of the conductive plug EP is connected to the conductive pattern 14, and the other end (−Z side end) is connected to the conductive pattern 121_1.

The conductive pattern 121_2 is disposed on the −Z side of the conductive pattern 12 and the conductive pattern 14. The conductive pattern 121_2 is disposed on the +Y side of the conductive pattern 121_1. The conductive pattern 121_2 is electrically connected between the conductive pattern 12 and the conductive pattern 14. The conductive pattern 121_2 may have a linear shape in XY plan view. The conductive pattern 121_2 extends in the X direction. The conductive pattern 121_2 extends in the X direction from the XY position of the conductive plug EP and reaches the XY position of the heat conductive plug TP3. The conductive pattern 121_2 has one end connected to the conductive pattern 12 via the heat conductive plug TP3 and the other end connected to the conductive pattern 14 via the conductive plug EP.

Some of the heat conductive plugs TP3 in the heat conductive plugs TP3_1 to TP3_k are arranged in the vicinity of the XY position of one end (+X side end) of the conductive pattern 121_2. One end (+Z side end) of the heat conductive plug TP3 is connected to the conductive pattern 12, and the other end (−Z side end) is connected to the conductive pattern 121_2.

Some of the conductive plugs EP in the conductive plugs EP_1 to EP_m are arranged in the vicinity of the XY position of the other end (−X side end) of the conductive pattern 121_2. One end (+Z side end) of the conductive plug EP is connected to the conductive pattern 14, and the other end (−Z side end) is connected to the conductive pattern 121_2.

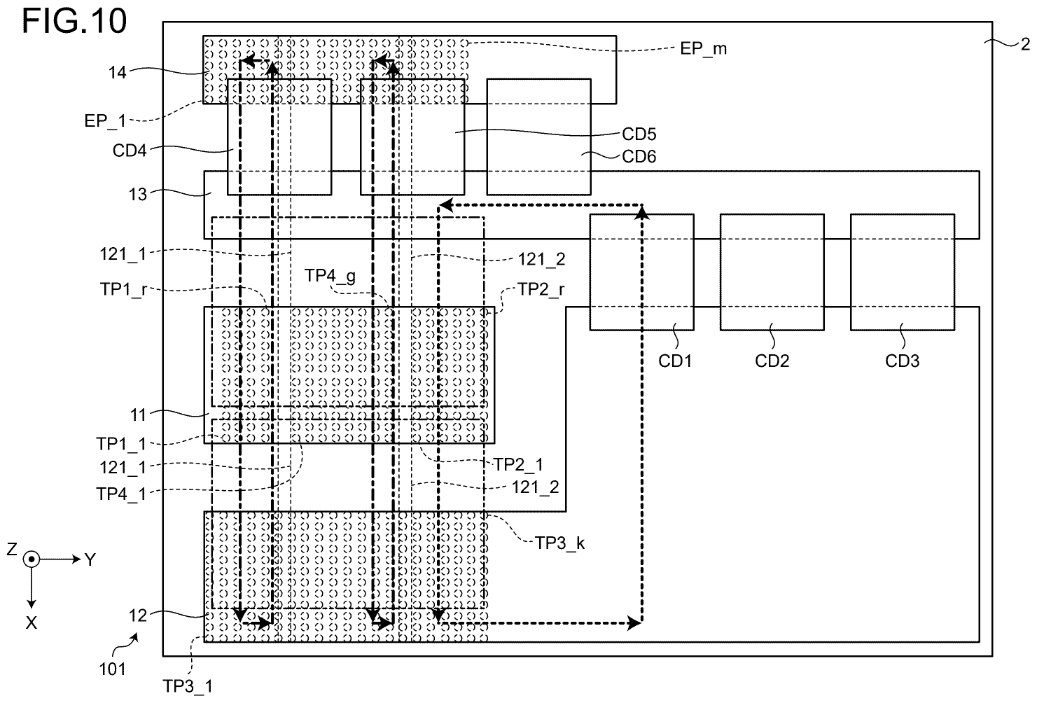

In the power module 101, as indicated by a dotted arrow in FIG. 10, a loop of the conductive pattern 13→the power device PD1→the conductive pattern 11→the power device PD2→the conductive pattern 12→the capacitive devices CD1 to CD3→the conductive pattern 13 forms a lateral loop.

In the power module 101, as indicated by one-dot chain line arrows in FIG. 10, a loop of the conductive pattern 13→the power device PD1→the conductive pattern 11→the power device PD2→the conductive pattern 12→the heat conductive plugs TP3_1 to TP3_k→the conductive pattern 121_1→the conductive plugs EP_1 to EP_m→the conductive pattern 14→the capacitive devices CD4 to CD6→the conductive pattern 13 forms a vertical loop.

In the power module 101, a loop of the conductive pattern 13→the power device PD1→the conductive pattern 11→the power device PD2→the conductive pattern 12→the heat conductive plugs TP3_1 to TP3_k→the conductive pattern 121_2→the conductive plugs EP_1 to EP_m→the conductive pattern 14→the capacitive devices CD4 to CD6→the conductive pattern 13 forms another vertical loop.

That is, in the power module 101, a hybrid structure of one lateral loop and multiple vertical loops is configured. In FIGS. 8 to 10, a configuration in which two conductive patterns 121_1 and 121_2 are arranged in the wiring layer L2 is exemplified, but the number of conductive patterns 121 arranged in the wiring layer L2 may be three or more. Accordingly, the number of vertical loops included in the hybrid structure may be three or more.

For example, in the power module 101, the conductive patterns 121_1 and 121_2 of the wiring layer L2 can each be miniaturized while improving the high-frequency characteristics. A width in the Y direction of each of the conductive patterns 121 is narrower than the width in the Y direction of the power device PD1. The width in the Y direction of each of the conductive patterns 121 is narrower than the width in the Y direction of the power device PD2. Thus, the parasitic capacitance affecting the output capacitance of the power devices PD1 and PD2 can be suppressed, and the switching loss of the power devices PD1 and PD2 can be suppressed.

Since the conductive patterns 121_1 and 121_2 can each be miniaturized, as illustrated in FIGS. 9 and 3, a wide XY region where the conductive patterns of the wiring layers L2, L3, and L4 do not generally exist can be ensured between the power devices PD1 and PD2 and the heat dissipation members 100 and 200 in the Z direction.

For example, in the arrangement region of the conductive pattern 11 overlapping the power devices PD1 and PD2 when viewed transparently from the Z direction, the heat conductive plugs TP1_1 to TP1_r, TP4_1 to TP4_g, and TP2_1 to TP2_r can be arranged in a region excluding the linear conductive patterns 121_1 and 121_2. The heat conductive plugs TP1_1 to TP1_r are arranged on the −Y side of the conductive pattern 121_1 in the arrangement region of the conductive pattern 11. The heat conductive plugs TP4_1 to TP4_g are arranged between the conductive patterns 121_1 and 121_2 in the arrangement region of the conductive pattern 11. The heat conductive plugs TP2_1 to TP2_r are arranged on the +Y side of the conductive pattern 121_2 in the arrangement region of the conductive pattern 11.

It is similar to the first embodiment in that the heat conductive plugs TP3_1 to TP3_k can be arranged in the arrangement region of the conductive pattern 12 overlapping the power device PD2 when viewed transparently from the Z direction.

Thus, the numbers r, r, k, and g of the heat conductive plugs TP1, TP2, TP3, and TP4 between the power devices PD1 and PD2 and the heat dissipation members 100 and 200 can be increased, the heat of the power devices PD1 and PD2 can be efficiently transmitted to the heat dissipation members 100 and 200, and the heat can be efficiently dissipated from the heat dissipation members 100 and 200.

As described above, in the second embodiment, in the power module 101, a hybrid structure of one lateral loop and multiple vertical loops is configured. Thus, a current can flow through more vertical loops as compared with a hybrid structure of one lateral loop and one vertical loop. As a result, the power module 101 can further suppress the parasitic inductance of the power loop, and can further improve the high-frequency characteristics.

### Third Embodiment

Next, a power module according to a third embodiment will be described. Hereinafter, differences from the first embodiment and the second embodiment will be mainly described.

Although in the first embodiment, a hybrid structure of one lateral loop and one vertical loop is illustrated, in the third embodiment, a hybrid structure of multiple lateral loops and one vertical loop is illustrated.

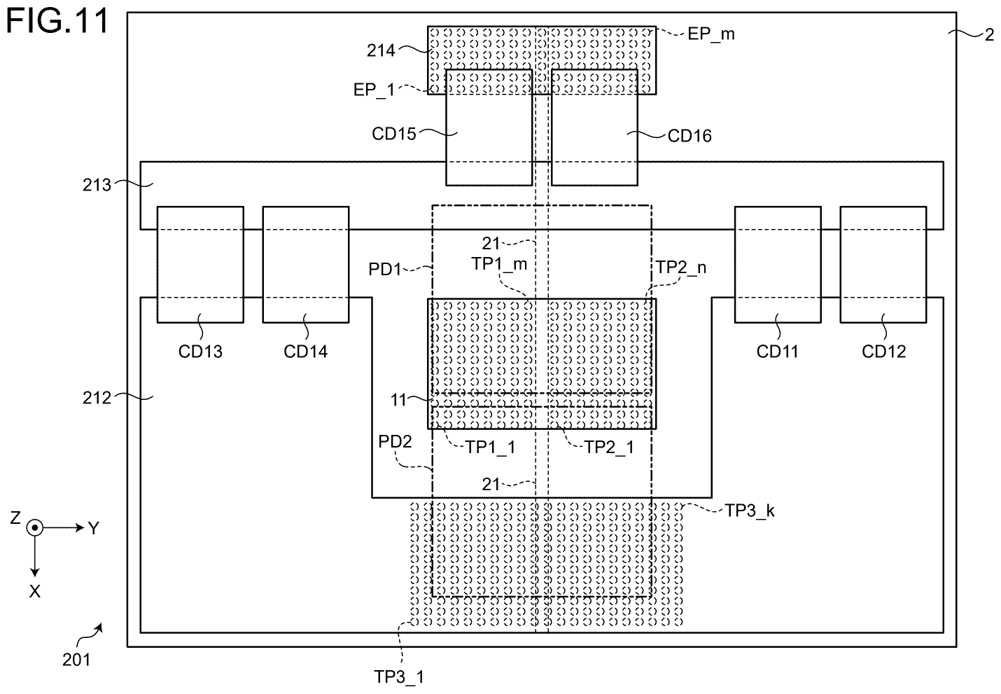

The power module 201 can be configured as illustrated in FIG. 11. FIG. 11 is a plan view illustrating a configuration of the power module 201.

As illustrated in FIG. 11, the wiring layer L1 includes a conductive pattern 212, a conductive pattern 213, and a conductive pattern 214 instead of the conductive pattern 12, the conductive pattern 13, and the conductive pattern 14 (see FIG. 2). Capacitive devices CD11 to CD16 are disposed in the wiring layer L1.

The conductive pattern 212 is electrically connected between the power device PD2 and the capacitive devices CD11 to CD14. A central portion of the conductive pattern 212 in the Y direction is electrically connected to one end of the conductive pattern 11 and one end of the heat conductive plug TP3 via the power device PD2.

The conductive pattern 212 extends from the position of the heat conductive plug TP3 to a position separated to the +Y side with respect to the power device PD2, and is bent from the separated position to the −X side and extends in the X direction. An end portion of the conductive pattern 212 on the +Y side is electrically connected to the other end of the conductive pattern 11 via the capacitive devices CD11 and CD12, the conductive pattern 213, and the power device PD1.

The conductive pattern 212 extends from the position of the heat conductive plug TP3 to a position separated to the −Y side with respect to the power device PD2, and is bent from the separated position to the −X side and extends in the X direction. An end portion of the conductive pattern 212 on the −Y side is electrically connected to the other end of the conductive pattern 11 via the capacitive devices CD13 and CD14, the conductive pattern 213, and the power device PD1. The conductive pattern 212 may have a substantially U shape in XY plan view.

The capacitive devices CD11 and CD12 are electrically connected between the conductive pattern 11 and the conductive pattern 212 on the +Y side of the conductive pattern 213. Each of the capacitive devices CD11 and CD12 may have a substantially rectangular shape in XY plan view. One end of each of the capacitive devices CD11 and CD12 is connected to the end portion of the conductive pattern 212 on the +Y side and the other end thereof is connected to the conductive pattern 213 in the X direction.

The capacitive devices CD13 and CD14 are electrically connected between the conductive pattern 212 and the conductive pattern 213 on the −Y side of the conductive pattern 11. Each of the capacitive devices CD13 and CD14 may have a substantially rectangular shape in XY plan view. One end of each of the capacitive devices CD13 and CD14 is connected to the end portion of the conductive pattern 212 on the −Y side end and the other end thereof is connected to the conductive pattern 213 in the X direction.

The conductive pattern 213 is disposed between the conductive pattern 11, the conductive pattern 212, and the conductive pattern 214 in the X direction. The conductive pattern 213 mainly extends in the Y direction. The conductive pattern 213 may have a substantially lateral I-shape in XY plan view. A portion of the conductive pattern 213 on the +X side and the +Y side is connected to the end portion of the conductive pattern 212 on the +Y side via the capacitive devices CD11 and CD12. A portion of the conductive pattern 213 on the +X side and the −Y side is connected to the end portion of the conductive pattern 212 on the −Y side via the capacitive devices CD13 and CD14. In the conductive pattern 213, a portion on the −X side is connected to the conductive pattern 214 via capacitive devices CD15 and CD16, and a central portion in the Y direction on the +X side is connected to the conductive pattern 11 via the power device PD1.

The capacitive devices CD15 and CD16 are electrically connected between the conductive pattern 213 and the conductive pattern 214. Each of the capacitive devices CD15 and CD16 may have a substantially rectangular shape in XY plan view. Each of the capacitive devices CD15 and CD16 may have the X direction as a longitudinal direction and the Y direction as a shorter direction. One end of each of the capacitive devices CD15 and CD16 is connected to the conductive pattern 213 and the other end thereof is connected to the conductive pattern 214 in the X direction.

The conductive pattern 214 is disposed on the −X side of the conductive pattern 213. The conductive pattern 214 mainly extends in the Y direction. The conductive pattern 214 may have a substantially rectangular shape in XY plan view. A portion of the conductive pattern 214 on the +X side is connected to the conductive pattern 213 via the capacitive devices CD15 and CD16.

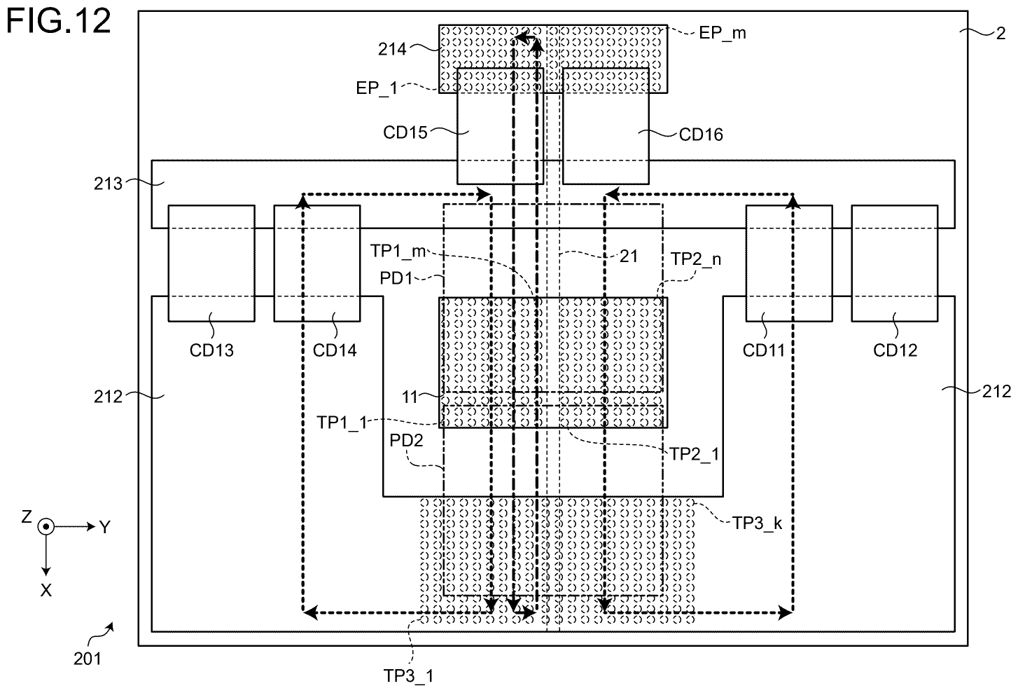

In the power module 201, as indicated on the +Y side by a dotted arrow in FIG. 12, a loop of the conductive pattern 213→the power device PD1→the conductive pattern 11→the power device PD2→the conductive pattern 212→the capacitive devices CD11 and CD12→the conductive pattern 213 forms a lateral loop.

In the power module 201, as indicated on the −Y side by a dotted arrow in FIG. 12, a loop of the conductive pattern 213→the power device PD1→the conductive pattern 11→the power device PD2→the conductive pattern 212→the capacitive devices CD13 and CD14→the conductive pattern 213 forms a lateral loop.

In the power module 201, as indicated by one-dot chain line arrows in FIG. 12, a loop of the conductive pattern 213→the power device PD1→the conductive pattern 11→the power device PD2→the conductive pattern 212→the heat conductive plugs TP3_1 to TP3_k→the conductive pattern 21→the conductive plugs EP_1 to EP_m→the conductive pattern 214→the capacitive devices CD15 and CD16→the conductive pattern 213 forms a vertical loop.

That is, in the power module 201, a hybrid structure of multiple lateral loops and one vertical loop is configured. In FIGS. 11 and 12, a hybrid structure of two lateral loops and one vertical loop is illustrated, but the number of lateral loops included in the hybrid structure may be 3 or more.

As described above, in the third embodiment, a hybrid structure of multiple lateral loops and one vertical loop is configured in the power module 201. Thus, a current can flow through more lateral loops as compared with a hybrid structure of one lateral loop and one vertical loop. As a result, the power module 201 can further suppress the parasitic inductance of the power loop, and can further improve the high-frequency characteristics.

### Fourth Embodiment

Next, a power module according to a fourth embodiment will be described. Hereinafter, differences from the first to third embodiments will be mainly described.

Although in the first embodiment, a configuration in which the conductive pattern 21 of the wiring layer L2 in the vertical loop is linear is exemplified, in the fourth embodiment, a configuration in which a conductive pattern 321 of the wiring layer L2 in the vertical loop meanders so as to bypass the −Z side of the conductive pattern 11 is exemplified.

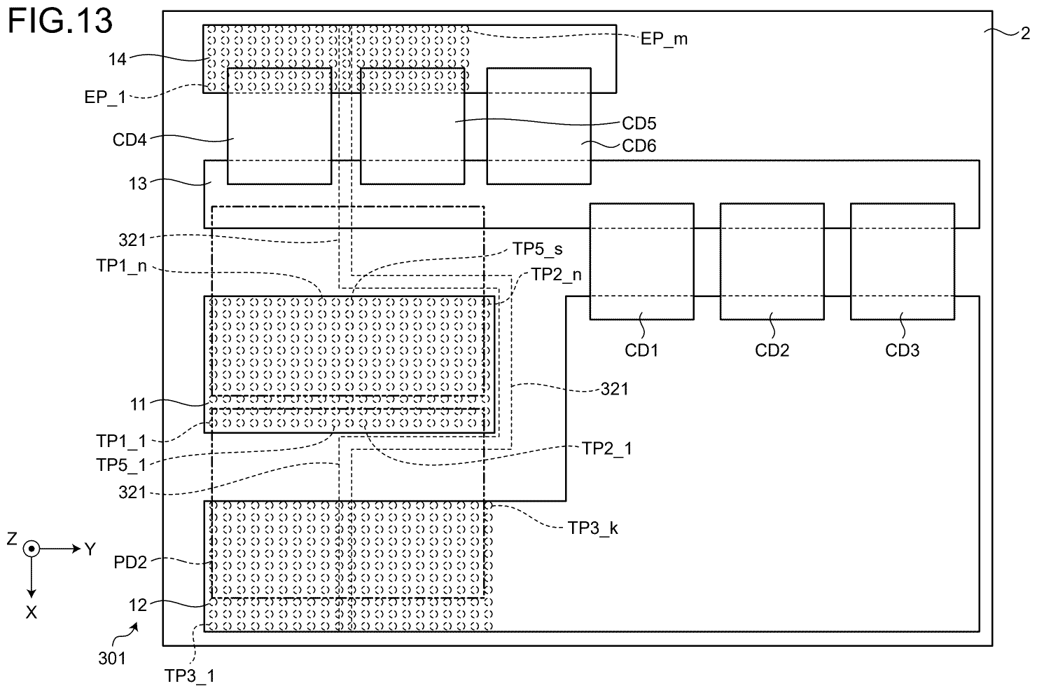

The power module 301 can be configured as illustrated in FIG. 13. FIG. 13 is an XY plan view illustrating a configuration of the power module 301.

The wiring layer L2 includes a conductive pattern 321 instead of the conductive pattern 21 (see FIG. 2). The conductive pattern 321 is similar to the conductive pattern 21 in that it has a linear shape in XY plan view, but is different from the conductive pattern 21 in that it is not linear and meanders so as to bypass the −Z side of the conductive pattern 11.

When extending in the X direction from an XY position of the heat conductive plug TP3 and reaching the +X side end of the conductive pattern 11, the conductive pattern 321 extends to the vicinity of the +Y side end of the conductive pattern 11 in the Y direction along the +X side end of the conductive pattern 11. When extending in the X direction along the conductive pattern 11 and reaching the vicinity of the-X side end of the conductive pattern 11, the conductive pattern 321 extends to a Y position of the conductive plug EP to be connected in the Y direction along the −X side end of the conductive pattern 11. The conductive pattern 321 extends in the X direction from there and reaches the XY position of the conductive plug EP.

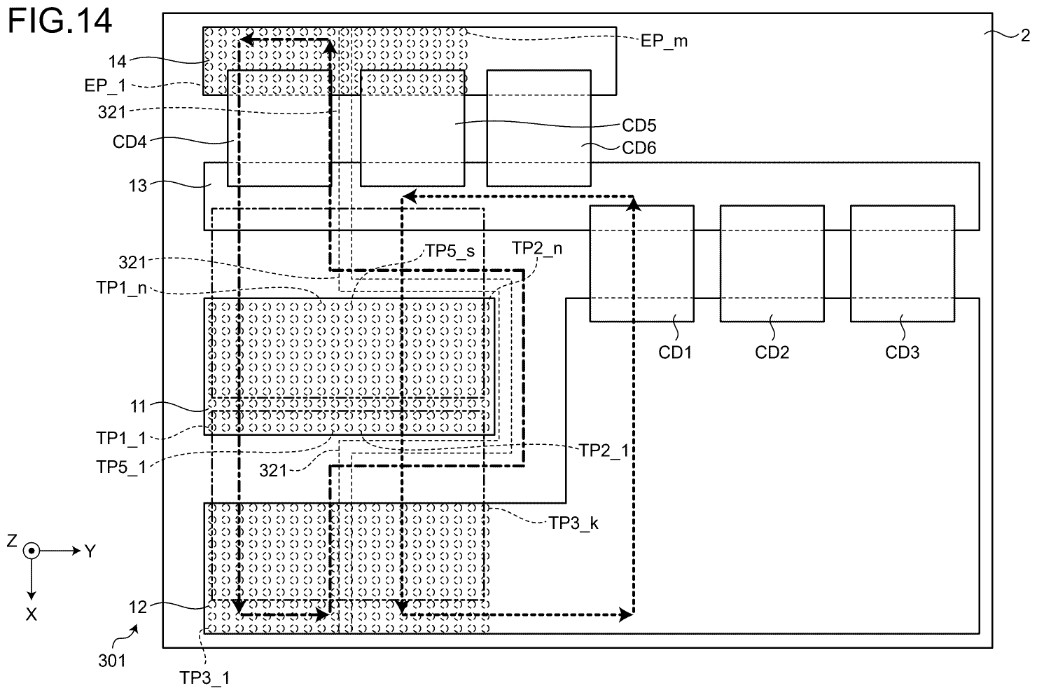

In the power module 301, as indicated by dotted arrows in FIG. 14, a loop of the conductive pattern 13→the power device PD1→the conductive pattern 11→the power device PD2→the conductive pattern 12→the capacitive devices CD1 to CD3→the conductive pattern 13 forms a lateral loop.

In the power module 301, as indicated by one-dot chain line arrows in FIG. 14, a loop of the conductive pattern 13→the power device PD1→the conductive pattern 11→the power device PD2→the conductive pattern 12→the heat conductive plugs TP3_1 to TP3_k→the conductive pattern 321→the conductive plugs EP_1 to EP_m→the conductive pattern 14→the capacitive devices CD4 to CD6→the conductive pattern 13 forms a vertical loop.

That is, in the power module 301, a hybrid structure of one lateral loop and one vertical loop is configured.

In this structure, as illustrated in FIGS. 13 and 3, it is possible to ensure a wider XY region where the conductive patterns of the wiring layers L2, L3, and L4 do not exist between the power devices PD1 and PD2 and the heat dissipation members 100 and 200 in the Z direction.

For example, when viewed transparently from the Z direction, in the arrangement region of the conductive pattern 11 overlapping the power devices PD1 and PD2, the heat conductive plugs can also be arranged in a region corresponding to the Y position of the conductive pattern 21 (see FIG. 2). In addition to the heat conductive plugs TP1_1 to TP1_n and TP2_1 to TP2_n, the heat conductive plugs TP5_1 to TP5_s can be arranged. s is any integer equal to or more than 2. The heat conductive plugs TP5_1 to TP5_s are arranged between the heat conductive plugs TP1_1 to TP1_n and the heat conductive plugs TP2_1 to TP2_n in the Y direction.

As described above, in the fourth embodiment, the conductive pattern 321 of the wiring layer L2 in the vertical loop meanders so as to bypass the XY region on the −Z side of the conductive pattern 11. Thus, in the arrangement region of the conductive pattern 11, an XY region in which the conductive patterns of the wiring layers L2, L3, and L4 do not substantially exist can be ensured to be wider between the power devices PD1 and PD2 and the heat dissipation members 100 and 200 in the Z direction. As a result, the number of the heat conductive plugs TP between the power devices PD1 and PD2 and the heat dissipation members 100 and 200 can be further increased, the heat of the power devices PD1 and PD2 can be efficiently transmitted to the heat dissipation members 100 and 200, and the heat can be efficiently dissipated from the heat dissipation members 100 and 200.

### Fifth Embodiment

Next, a power module according to a fifth embodiment will be described. Hereinafter, differences from the first to fourth embodiments will be mainly described.

Although in the fourth embodiment, a configuration in which one conductive pattern 321 of the wiring layer L2 in the vertical loop meanders so as to bypass the −Z side of the conductive pattern 11 is exemplified, in the fifth embodiment, a configuration in which multiple conductive patterns 421_1 and 421_2 of the wiring layer L2 in the vertical loop meanders so as to bypass the −Z side of the conductive pattern 11 is exemplified.

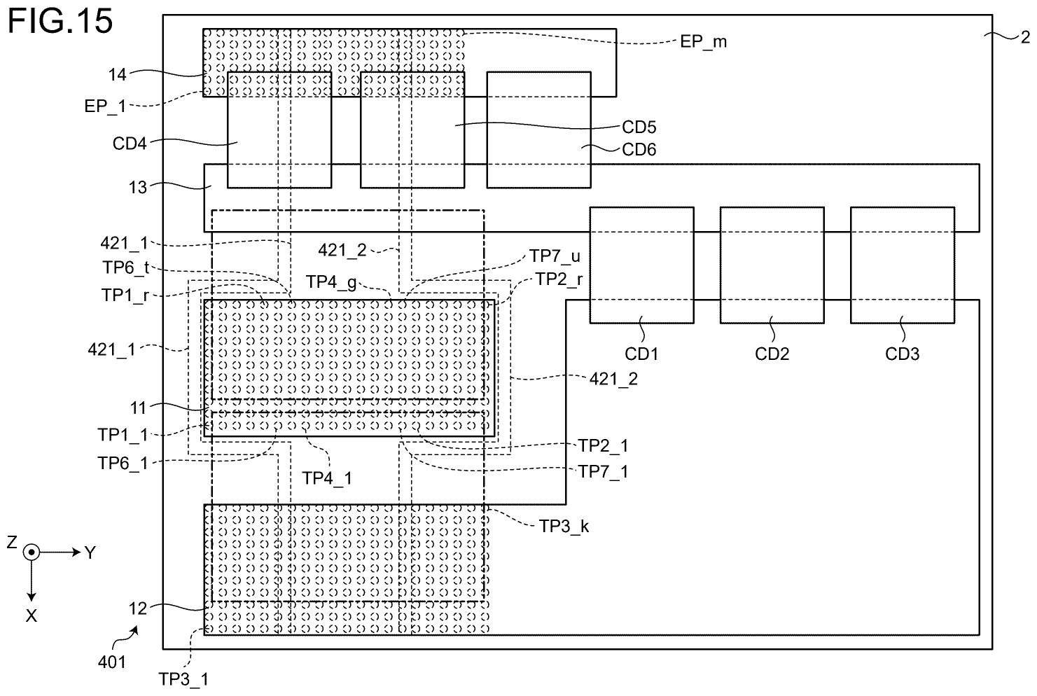

The power module 401 can be configured as illustrated in FIG. 15. FIG. 15 is an XY plan view illustrating a configuration of the power module 401.

The wiring layer L2 includes conductive patterns 421_1 and 421_2 instead of the conductive patterns 121_1 and 121_2 (see FIG. 9). Each of the conductive patterns 421 is similar to each of the conductive patterns 121 in that the conductive pattern is linear in XY plan view, but is different from the conductive pattern 121 in that the conductive pattern is not linear and meanders so as to bypass the −Z side of the conductive pattern 11.

When extending in the X direction from an XY position of the heat conductive plug TP3 and reaching the +X side end of the conductive pattern 11, the conductive pattern 421_1 extends to the vicinity of the −Y side end of the conductive pattern 11 in the Y direction along the +X side end of the conductive pattern 11. When extending in the X direction along the conductive pattern 11 and reaching the vicinity of the −X side end of the conductive pattern 11, the conductive pattern 421_1 extends to a Y position of the conductive plug EP to be connected in the Y direction along the −X side end of the conductive pattern 11. The conductive pattern 421_1 extends in the X direction from there and reaches the XY position of the conductive plug EP.

When extending in the X direction from an XY position of the heat conductive plug TP3 and reaching the +X side end of the conductive pattern 11, the conductive pattern 421_2 extends to the vicinity of the +Y side end of the conductive pattern 13 in the Y direction along the +X side end of the conductive pattern 11. When extending in the X direction along the conductive pattern 11 and reaching the vicinity of the −X side end of the conductive pattern 11, the conductive pattern 421_2 extends to a Y position of the conductive plug EP to be connected in the Y direction along the −X side end of the conductive pattern 11. The conductive pattern 421_2 extends in the X direction from there and reaches the XY position of the conductive plug EP.

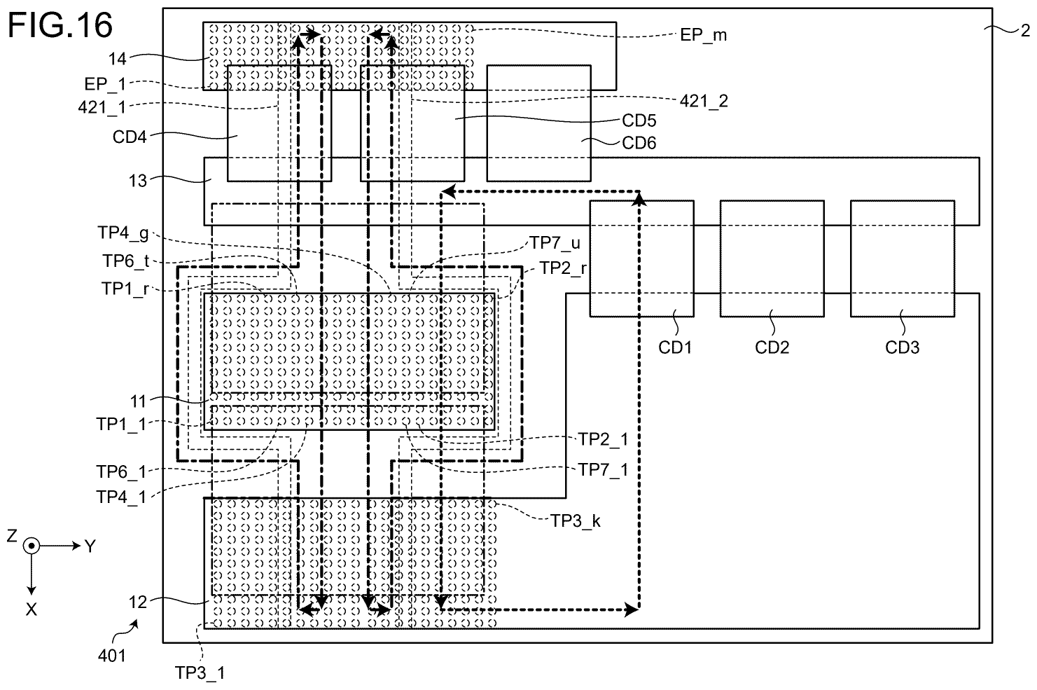

In the power module 401, as indicated by a dotted arrow in FIG. 16, a loop of the conductive pattern 13→the power device PD1→the conductive pattern 11→power device PD2→the conductive pattern 12→the capacitive devices CD1 to CD3→the conductive pattern 13 forms a lateral loop.

In the power module 401, as indicated on the −Y side by one-dot chain line arrows in FIG. 16, a loop of the conductive pattern 13→the power device PD1→the conductive pattern 11→the power device PD2→the conductive pattern 12→the heat conductive plugs TP3_1 to TP3_k→the conductive pattern 421_1→the conductive plugs EP_1 to EP_m→the conductive pattern 14→the capacitive devices CD4 to CD6→the conductive pattern 13 forms a vertical loop.

In the power module 401, as indicated on the +Y side by one-dot chain line arrows in FIG. 16, a loop of the conductive pattern 13→the power device PD1→the conductive pattern 11→the power device PD2→the conductive pattern 12→the heat conductive plugs TP3_1 to TP3_k→the conductive pattern 421_2→the conductive plugs EP_1 to EP_m→the conductive pattern 14→the capacitive devices CD4 to CD6→the conductive pattern 13 forms a vertical loop.

That is, in the power module 401, a hybrid structure of one lateral loop and multiple vertical loops is configured.

In this structure, as illustrated in FIGS. 15 and 3, it is possible to ensure a wider XY region where the conductive patterns of the wiring layers L2, L3, and L4 do not substantially exist between the power devices PD1 and PD2 and the heat dissipation members 100 and 200 in the Z direction.

For example, when viewed transparently from the Z direction, in the arrangement region of the conductive pattern 11 overlapping the power devices PD1 and PD2, the heat conductive plugs can also be arranged in a region corresponding to the Y position of the conductive patterns 121_1 and 121_2 (see FIG. 2). In addition to the heat conductive plugs TP1_1 to TP1_r, TP4_1 to TP4_g, and TP2_1 to TP2_r, the heat conductive plugs TP6_1 to TP6_t and TP7_1 to TP7_u can be arranged. Each of t and u is any integer of 2 or more. The heat conductive plugs TP6_1 to TP6_t are arranged between the heat conductive plugs TP1_1 to TP1_r and the heat conductive plugs TP4_1 to TP4_g in the arrangement region of the conductive pattern 11. The heat conductive plugs TP7_1 to TP7_u are arranged between the heat conductive plugs TP4_1 to TP4_g and the heat conductive plugs TP2_1 to TP2_r in the arrangement region of the conductive pattern 11.

As described above, in the fifth embodiment, in the power module 401, a hybrid structure of one lateral loop and multiple vertical loops is configured. Thus, a current can flow through more vertical loops as compared with a hybrid structure of one lateral loop and one vertical loop. As a result, the power module 401 can further suppress the parasitic inductance of the power loop, and can further improve the high-frequency characteristics.

Further, in the fifth embodiment, in the power module 401, each of the conductive patterns 421_1 and 421_2 of the multiple vertical loops meanders so as to bypass the −Z side of the conductive pattern 11. Thus, it is possible to ensure a wider XY region where the conductive patterns of the wiring layers L2, L3, and L4 do not substantially exist between the power devices PD1 and PD2 and the heat dissipation members 100 and 200 in the Z direction. As a result, the number of the heat conductive plugs TP between the power devices PD1 and PD2 and the heat dissipation members 100 and 200 can be further increased, the heat of the power devices PD1 and PD2 can be efficiently transmitted to the heat dissipation members 100 and 200, and the heat can be efficiently dissipated from the heat dissipation members 100 and 200.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power module comprising:
a first conductive pattern included in the first layer;
a second conductive pattern disposed on the first layer;
a first power device disposed between the first conductive pattern and the second conductive pattern in the first layer;
a third conductive pattern disposed on the first layer;
a first capacitive element disposed between the second conductive pattern and the third conductive pattern in the first layer;
a fourth conductive pattern disposed on the first layer;
a second capacitive element disposed between the third conductive pattern and the fourth conductive pattern in the first layer;
a first conductive plug extending from the first layer to the second layer, and having one end electrically connected to one end of the second conductive pattern;
a fifth conductive pattern included in the second layer, and having one end electrically connected to another end of the first conductive plug;
a second conductive plug extending from the second layer to the first layer, and having one end electrically connected to another end of the fifth conductive pattern and another end electrically connected to the fourth conductive pattern; and
a second power device disposed between the first conductive pattern and the third conductive pattern in the first layer, wherein
a first power loop including the first conductive pattern, the first power device, the second conductive pattern, the first capacitive element, the third conductive pattern, and the second power device, and a second power loop including the first conductive pattern, the first power device, the first conductive plug, the fifth conductive pattern, the second conductive plug, the fourth conductive pattern, the second capacitive element, the third conductive pattern, and the second power device are formed.

2. The power module according to claim 1, wherein
a width in a shorter direction of the fifth conductive pattern is narrower than a width in a shorter direction of the first power device and narrower than a width in a shorter direction of the second power device.

3. The power module according to claim 1, further comprising:
a third conductive plug extending from the first layer to the second layer, and having one end electrically connected to one end of the second conductive pattern;
one or more sixth conductive patterns included in the second layer, and having one end electrically connected to another end of the third conductive plug; and
a fourth conductive plug extending from the second layer to the first layer, and having one end electrically connected to another end of the one or more sixth conductive patterns and another end electrically connected to the fourth conductive pattern, wherein
one or more third power loops including the first conductive pattern, the first power device, the third conductive plug, the sixth conductive pattern, the fourth conductive plug, the fourth conductive pattern, the second capacitive element, the third conductive pattern, and the second power device are further formed.

4. The power module according to claim 3, wherein
a width in a shorter direction of the fifth conductive pattern is narrower than a width in a shorter direction of the first power device and narrower than a width in a shorter direction of the second power device, and
a width in a shorter direction of each of the one or more sixth conductive patterns is narrower than the width in the shorter direction of the first power device and narrower than the width in the shorter direction of the second power device.

5. The power module according to claim 1, further comprising:
a third capacitive element disposed on an opposite side of the first capacitive element with the first conductive pattern interposed therebetween and disposed between the second conductive pattern and the third conductive pattern in the first layer, wherein
a fourth power loop including the first conductive pattern, the first power device, the second conductive pattern, the third capacitive element, the third conductive pattern, and the second power device is further formed.

6. The power module according to claim 5, wherein
a width in a shorter direction of the fifth conductive pattern is narrower than a width in a shorter direction of the first power device and narrower than a width in a shorter direction of the second power device.

7. The power module according to claim 1, further comprising:
a heat dissipation member disposed in a third layer opposite to the first layer with the second layer interposed therebetween, the heat dissipation member having a structure capable of dissipating heat; and
a heat conductive plug extending from the first layer through the second layer to the third layer, and having one end in thermal contact with the first power device or the second power device and another end in thermal contact with the heat dissipation member.

8. The power module according to claim 7, wherein
the fifth conductive pattern overlaps a part of a first region overlapping the first power device or the second power device in a first arrangement region of the first conductive pattern when viewed transparently from a direction perpendicular to a main surface of the first power device, and
the heat conductive plug is disposed in a region excluding the fifth conductive pattern in the first region when viewed transparently from the direction perpendicular to the main surface of the first power device.

9. The power module according to claim 7, further comprising:
a second heat conductive plug extending from the first layer through the second layer to the third layer, and having one end in thermal contact with the second power device and another end in thermal contact with the heat dissipation member, wherein
the fifth conductive pattern overlaps a part of a second region overlapping the second power device in an arrangement region of the second conductive pattern when viewed transparently from a direction perpendicular to a main surface of the first power device, and
the second heat conductive plug is disposed in a region excluding the fifth conductive pattern in the second region when viewed transparently from the direction perpendicular to the main surface of the first power device.

10. The power module according to claim 7, further comprising:
a second heat conductive plug extending from the first layer through the second layer to the third layer, and having one end in thermal contact with the second power device and another end in thermal contact with the heat dissipation member, wherein
the fifth conductive pattern overlaps a part of a first region overlapping the first power device or the second power device in an arrangement region of the first conductive pattern when viewed transparently from a direction perpendicular to a main surface of the first power device,
the heat conductive plug is disposed in a region excluding the fifth conductive pattern in the first region when viewed transparently from the direction perpendicular to the main surface of the first power device,
the fifth conductive pattern overlaps a part of a second region overlapping the second power device in an arrangement region of the second conductive pattern when viewed transparently from the direction perpendicular to the main surface of the first power device, and
the second heat conductive plug is disposed in a region excluding the fifth conductive pattern in the second region when viewed transparently from the direction perpendicular to the main surface of the first power device.

11. The power module according to claim 3, further comprising:
a heat dissipation member disposed in a third layer opposite to the first layer with the second layer interposed therebetween, the heat dissipation member having a structure capable of dissipating heat; and
a heat conductive plug extending from the first layer through the second layer to the third layer, and having one end in thermal contact with the first power device or the second power device and another end in thermal contact with the heat dissipation member.

12. The power module according to claim 11, wherein
the fifth conductive pattern overlaps a part of a first region overlapping the first power device or the second power device in an arrangement region of the first conductive pattern when viewed transparently from a direction perpendicular to a main surface of the first power device,
the sixth conductive pattern overlaps another part of the first region when viewed transparently from the direction perpendicular to the main surface of the first power device, and
the heat conductive plug is disposed in a region excluding the fifth conductive pattern and the sixth conductive pattern in the first region when viewed transparently from the direction perpendicular to the main surface of the first power device.

13. The power module according to claim 11, further comprising:
a second heat conductive plug extending from the first layer through the second layer to the third layer, and having one end in thermal contact with the second power device and another end in thermal contact with the heat dissipation member, wherein
the fifth conductive pattern overlaps a part of a second region overlapping the second power device in an arrangement region of the second conductive pattern when viewed transparently from a direction perpendicular to a main surface of the first power device,
the sixth conductive pattern overlaps another part of the second region when viewed transparently from the direction perpendicular to the main surface of the first power device, and
the second heat conductive plug is disposed in a region excluding the fifth conductive pattern and the sixth conductive pattern in the second region when viewed transparently from the direction perpendicular to the main surface of the first power device.

14. The power module according to claim 11, further comprising:
a second heat conductive plug extending from the first layer through the second layer to the third layer, and having one end in thermal contact with the second power device and another end in thermal contact with the heat dissipation member, wherein
the fifth conductive pattern overlaps a part of a first region overlapping the first power device or the second power device in an arrangement region of the first conductive pattern when viewed transparently from a direction perpendicular to a main surface of the first power device,
the sixth conductive pattern overlaps another part of the first region when viewed transparently from the direction perpendicular to the main surface of the first power device,
the heat conductive plug is disposed in a region excluding the fifth conductive pattern and the sixth conductive pattern in the first region when viewed transparently from the direction perpendicular to the main surface of the first power device,
the fifth conductive pattern overlaps a part of a second region overlapping the second power device in an arrangement region of the second conductive pattern when viewed transparently from the direction perpendicular to the main surface of the first power device,
the sixth conductive pattern overlaps another part of the second region when viewed transparently from the direction perpendicular to the main surface of the first power device, and
the second heat conductive plug is disposed in a region excluding the fifth conductive pattern and the sixth conductive pattern in the second region when viewed transparently from the direction perpendicular to the main surface of the first power device.

15. The power module according to claim 1, wherein
the fifth conductive pattern extends in a meandering manner so as to bypass the first conductive pattern when viewed transparently from a direction perpendicular to a main surface of the first power device.

16. The power module according to claim 15, further comprising:
a heat dissipation member disposed in a third layer opposite to the first layer with the second layer interposed therebetween, the heat dissipation member having a structure capable of dissipating heat; and
a heat conductive plug extending from the first layer through the second layer to the third layer, and having one end in thermal contact with the first power device or the second power device, and another end in thermal contact with the heat dissipation member, wherein
the heat conductive plug is disposed in a first region overlapping the first power device or the second power device in a first arrangement region of the first conductive pattern when viewed transparently from the direction perpendicular to the main surface of the first power device.

17. The power module according to claim 16, further comprising:
a second heat conductive plug extending from the first layer through the second layer to the third layer, and having one end in thermal contact with the second power device and another end in thermal contact with the heat dissipation member, wherein
the second heat conductive plug is disposed in a second region overlapping the second power device in an arrangement region of the second conductive pattern when viewed transparently from the direction perpendicular to the main surface of the first power device.

18. The power module according to claim 3, wherein
the fifth conductive pattern extends in a meandering manner so as to bypass the first conductive pattern when transparently viewed from a direction perpendicular to the main surface of the first power device, and
the sixth conductive pattern extends in a meandering manner so as to bypass the first conductive pattern when viewed transparently from the direction perpendicular to the main surface of the first power device.

19. The power module according to claim 18, further comprising:
a heat dissipation member disposed in a third layer opposite to the first layer with the second layer interposed therebetween, the heat dissipation member having a structure capable of dissipating heat; and
a heat conductive plug extending from the first layer through the second layer to the third layer, and having one end in thermal contact with the first power device or the second power device, and another end in thermal contact with the heat dissipation member, wherein
the heat conductive plug is disposed in a first region overlapping the first power device or the second power device in a first arrangement region of the first conductive pattern when viewed transparently from the direction perpendicular to the main surface of the first power device.

20. The power module according to claim 19, further comprising:
a second heat conductive plug extending from the first layer through the second layer to the third layer, and having one end in thermal contact with the second power device and another end in thermal contact with the heat dissipation member, wherein
the second heat conductive plug is disposed in a second region overlapping the second power device in an arrangement region of the second conductive pattern when viewed transparently from the direction perpendicular to the main surface of the first power device.
